(19) United States
(12) Patent Application Publication
(10) Pub. No.: US 2024/0321922 A1
(43) Pub. Date: Sep. 26, 2024

(54) PIXEL, PIXEL ARRAY, AND IMAGE SENSORS INCLUDING THE PIXEL

(71) Applicant: Samsung Electronics Co., Ltd., Suwon-si (KR)

(72) Inventors: Sangchun PARK, Suwon-si (KR); Sungsoo CHOI, Suwon-si (KR); Seounghyun KIM, Suwon-si (KR)

(73) Assignee: Samsung Electronics Co., Ltd., Suwon-si (KR)

(21) Appl. No.: 18/612,035

(22) Filed: Mar. 21, 2024

(30) Foreign Application Priority Data
Mar. 24, 2023 (KR) 10-2023-0039268
May 18, 2023 (KR) 10-2023-0064560

(51) Int. Cl. H01L 27/146

(52) U.S. Cl. CPC H01L 27/1463; H01L 27/14607; H01L 27/14636; H01L 27/1464

(57) ABSTRACT

A pixel includes a semiconductor substrate including a first surface and a second surface, a plurality of photoelectric conversion regions between the first surface and the second surface of the semiconductor substrate, one or more floating diffusion regions on the first surface of the semiconductor substrate and spaced apart from the plurality of photoelectric conversion regions; a plurality of vertical transmission gates configured to surround a path of charges transferred from each photoelectric conversion region of the plurality of photoelectric conversion regions to the one or more floating diffusion regions; a floating diffusion region connection pad on the one or more floating diffusion regions; and a metal contact connected to the floating diffusion region connection pad.

### CROSS-REFERENCE TO RELATED APPLICATIONS

This application is based on and claims priority under 35 U.S.C. § 119 to Korean Patent Application No. 10-2023-0039268, filed on Mar. 24, 2023 in the Korean Intellectual Property Office, and Korean Patent Application No. 10-2023-0064560, filed on May 18, 2023 in the Korean Intellectual Property Office, the disclosures of each of which are incorporated by reference herein in their entireties.

### BACKGROUND

The inventive concepts relate to pixels and image sensors including one or more of such pixels.

The image sensor includes a semiconductor device converting an optical signal incident from the outside into an electrical signal, and generates image information corresponding to the incident optical signal. Recently, with the development of the computer industry and the communication industry, the demand for image sensors is increasing in various fields, such as digital cameras, camcorders, mobile phones, security cameras, and medical microcams.

In particular, because complementary metal-oxide semiconductor (CMOS) image sensors (CISs) using the CMOS have a simple driving method, and have analog circuits and digital signal processing circuits thereof integrated into a single chip, while products using CISs may be miniaturized and at the same time, the power consumption is low, the CISs are widely used as image sensors for mobile products or small products having limited battery capacity.

Recently, to improve the light receiving efficiency and photosensitivity of a CIS, a backside illumination method of receiving incident light through the backside of the substrate has been adopted, and a vertical transfer gate (VTG), which increases the transmission efficiency of photocharges by extending a transfer gate arranged on a front side of a substrate in a depth direction of the substrate to reduce a separation distance between the transfer gate and a photocharge storage unit, is used.

### SUMMARY

Some example embodiments of the inventive concepts provide a structure of a pixel array which may simplify different floating diffusion regions.

Some example embodiments of the inventive concepts provide a pixel.

According to some example embodiments, a pixel may include a semiconductor substrate including a first surface and a second surface, a plurality of photoelectric conversion regions between the first surface and the second surface of the semiconductor substrate, one or more floating diffusion regions on the first surface of the semiconductor substrate and spaced apart from the plurality of photoelectric conversion regions, a plurality of vertical transmission gates configured to surround a path of charges transferred from each photoelectric conversion region of the plurality of photoelectric conversion regions to the one or more floating diffusion regions, a floating diffusion region connection pad formed on the one or more floating diffusion regions, and a metal contact connected to the floating diffusion region connection pad.

Some example embodiments of the inventive concepts provide a pixel array.

According to some example embodiments, a pixel array may include a first pixel and a second pixel. The first pixel may include a first photoelectric conversion region, a second photoelectric conversion region, a first floating diffusion region, and first dual vertical transmission gates spaced apart from the first photoelectric conversion region and the second photoelectric conversion region. The second pixel may include a third photoelectric conversion region, a fourth photoelectric conversion region, a second floating diffusion region, and second dual vertical transmission gates spaced apart from the third photoelectric conversion region and the fourth photoelectric conversion region. The pixel array may include a floating diffusion region connection pad configured to physically connect the first floating diffusion region to the second floating diffusion region. The pixel array may include a metal contact connected to the floating diffusion region connection pad.

Some example embodiments of the inventive concepts provide an image sensor.

According to some example embodiments, an image sensor may include a pixel array including a plurality of pixels configured to respectively generate a plurality of pixel signals in response to incident light, and a signal processing circuit configured to output image data based on the plurality of pixel signals. At least one pixel of the plurality of pixels may include a semiconductor substrate including a first surface and a second surface, a plurality of photoelectric conversion regions between the first surface and the second surface, one or more floating diffusion regions on the first surface and spaced apart from the plurality of photoelectric conversion regions, a plurality of vertical transmission gates configured to surround a path of charges transferred from each photoelectric conversion region of the plurality of photoelectric conversion regions to the one or more floating diffusion regions, a floating diffusion region connection pad on the one or more floating diffusion regions, and a metal contact connected to the floating diffusion region connection pad. The image sensor may be a backside illumination (BSI) image sensor.

### BRIEF DESCRIPTION OF THE DRAWINGS

Some example embodiments will be more clearly understood from the following detailed description taken in conjunction with the accompanying drawings in which:

FIG. 1 is a block diagram of an image sensor according to some example embodiments;

FIG. 2 is a schematic circuit diagram of a pixel included in an image sensor, according to some example embodiments;

FIG. 3A is a plan view of a two photo diode (2PD) pixel according to some example embodiments;

FIG. 3B is a plan view of a pixel array including 2PD pixels, according to some example embodiments;

FIG. 3C is a cross-sectional view taken along line A-A′ in the plan view of FIG. 3B;

FIG. 3D is a cross-sectional view taken along line B-B′ of FIG. 3B;

FIG. 4A is a plan view of a 2PD pixel according to some example embodiments;

FIG. 4B is a plan view of a pixel array including 2PD pixels, according to some example embodiments;

FIGS. 5A, 5B, 5C, and 5D illustrate various embodiments capable of connecting floating diffusion nodes of 2PD pixels, according to some example embodiments; and

FIGS. 6A, 6B, 6C, 6D, 6E, 6F, 6G, 6H, 6I, and 6J respectively illustrate layout structures of pixel arrays including 2PD pixels, according to some example embodiments.

### DETAILED DESCRIPTION

Hereinafter, some example embodiments of the inventive concepts are described in conjunction with the accompanying drawings. The same reference numerals are used for the same components in the drawings, and descriptions already given for them are omitted.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

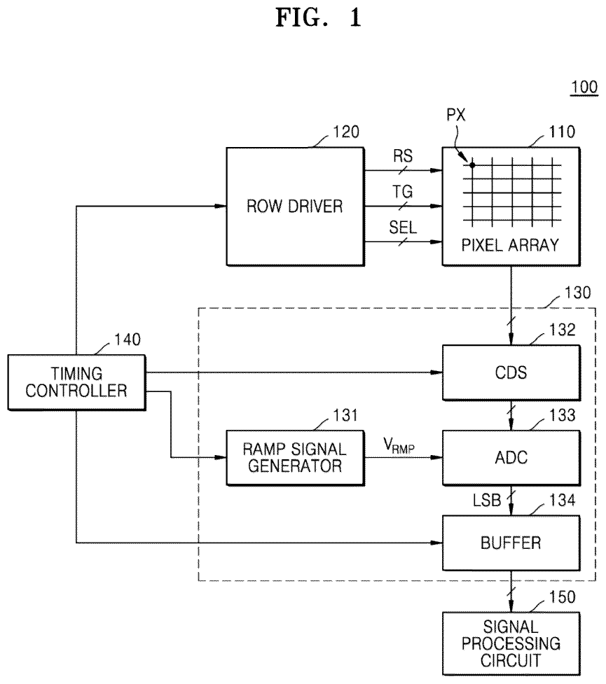

FIG. 1 is a block diagram of an image sensor 100 according to some example embodiments.

Referring to FIG. 1, the image sensor 100 according to some example embodiments may include a pixel array 110, a row driver 120, a readout circuit 130, a timing controller 140, and a signal processing circuit 150.

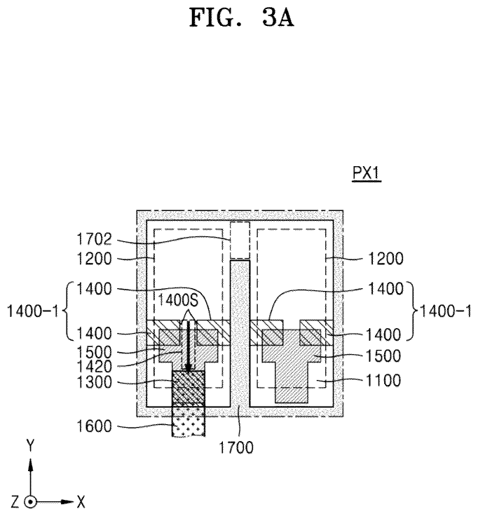

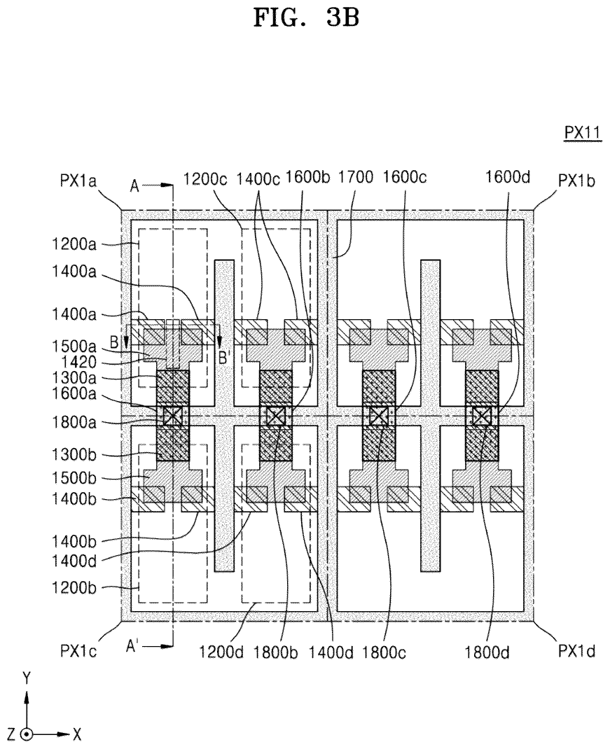

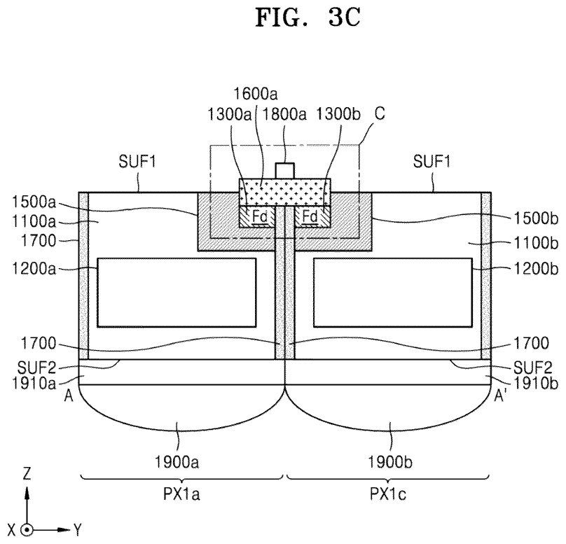

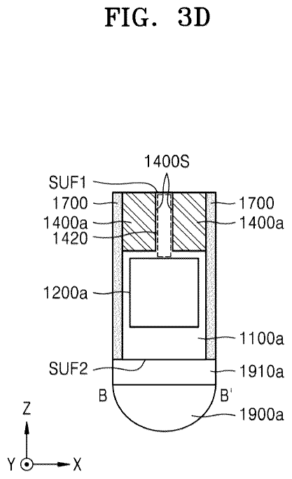

The image sensor 100 may generate image data by converting light received from the outside into an electrical signal. The pixel array 110 included in the image sensor 100 may include a plurality of pixels PX, and the plurality of pixels PX may include optical elements such as photodiodes (PDs), which receive light and generate charges. The plurality of pixels PX may be respectively connected to a plurality of row lines extending in a first direction and a plurality of column lines extending in a second direction. In some example embodiments, each of the plurality of pixels PX may also include two or more PDs. Each of the plurality of pixels PX may include two or more PDs so that each of the pixels PX generates a pixel signal corresponding to light of various colors, or performs an auto focus function. According to some example embodiments, each of the plurality of pixels PX may have a two photodiode (2PD) structure. Each of the pixels PX may include a floating diffusion region, and a plurality of floating diffusion regions may be connected to each other via a floating diffusion region connection pad. According to a structure of pixels according to the inventive concepts, a metal contact may be unified, and by preventing a capacitance increase of the floating diffusion region, a conversion gain may be secured, thereby improving operational performance and/or efficiency (e.g., reducing power consumption without compromising performance) of the pixels PX, and thus of the image sensor 100. The structure of each of the plurality of pixels PX is described below with reference to FIGS. 3A through 6J.

In some example embodiments, each of the plurality of pixels PX may include a pixel circuit for generating a pixel signal from charges generated by the PDs. In some example embodiments, the pixel circuit may include a transmission transistor, a driving transistor, a selection transistor, a reset transistor, the floating diffusion region, etc. The pixel circuit may obtain a pixel signal by detecting a reset voltage and a pixel voltage from each of the plurality of pixels PX, and calculating the difference therebetween. The pixel voltage may include a voltage reflecting charges generated by the PDs included in each of the plurality of pixels PX.

When the plurality of pixels PX include two or more PDs, each of the plurality of pixels PX may include a pixel circuit for processing charges generated by each of the two or more PDs. In other words, according to some example embodiments, the pixel circuit may include at least two of a transmission transistor, a driving transistor, a selection transistor, and a reset transistor.

The row driver 120 may drive the pixel array 110 in units of rows. A plurality of row drivers 120 may drive the pixel array 110 by inputting a driving signal to the row lines. For example, the driving signal may include a transmission control signal TG controlling the transmission transistor of the pixel circuit, a reset control signal RS controlling the reset transistor, and a selection control signal SEL controlling the selection transistor. In some example embodiments, the row driver 120 may sequentially drive a plurality of row lines.

The readout circuit 130 may include a ramp signal generator 131, a sampling circuit 132, an analog-to-digital converter (ADC) 133, and a buffer 134. The sampling circuit 132 may include the plurality of samplers connected to the pixels PX via the plurality of column lines, and in some example embodiments, the sampler may include correlated double samplers (CDS). The sampler may detect the reset voltage and the pixel voltage from the pixels PX connected to a selection row line driven by the row driver 120 among the plurality of row lines. The samplers may output the difference between the reset voltage and the pixel voltage as an analog signal.

The ADC 133 may compare the analog signal with a ramp voltage VRMP, convert the comparison result into a digital signal, and output the digital signal as image data LSB. The image data LSB may have a value that increases as the difference between the reset voltage and the pixel voltage increases. Accordingly, the image data LSB may have a value that increases as the amount of light received by the PD increases.

The buffer 134 may temporarily store the image data LSB received from the ADC 133.

The row driver 120 and the readout circuit 130 may be controlled by the timing controller 140. The timing controller 140 may control the operation timing of the row driver 120 and the readout circuit 130. The row driver 120 may control the operation of the pixel array 110 in units of rows according to the control of the timing controller 140.

The signal processing circuit 150 may generate an image by using the image data LSB transmitted by the buffer 134. The signal processing circuit 150 may process the image data LSB, and output the processed image data as an image.

In some example embodiments, the signal processing circuit 150 may interpolate image data LSB corresponding to the pixel signals output by the pixels PX, and generate interpolated image data. According to some example embodiments, the image sensor 100 may perform bad pixel correction (BPC) by using the pixel signals output by the PDs before the signal processing circuit 150 processes the image data LSB.

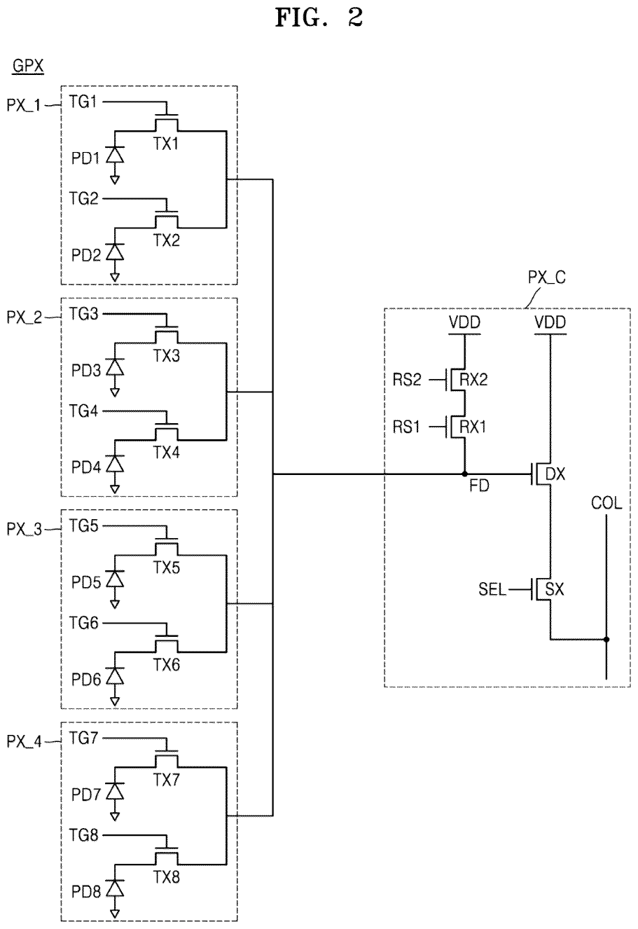

FIG. 2 is a schematic circuit diagram of the pixel PX included in the image sensor 100, according to some example embodiments.

Referring to FIG. 2, a pixel group GPX included in the image sensor 100 may include a pixel having a shared structure of the floating diffusion region. Referring to FIG. 2, the pixel group GPX may include a floating diffusion node FD, a first pixel PX_1, a second pixel PX_2, a third pixel PX_3, a fourth pixel PX_4, and a read circuit PX_C. The first pixel PX_1, the second pixel PX_2, the third pixel PX_3, and the fourth pixel PX_4 may be commonly connected to the floating diffusion node FD. The first pixel PX_1, the second pixel PX_2, the third pixel PX_3, and the fourth pixel PX_4 may be arranged in a 2×2 arrangement. According to some example embodiments, each of the first pixel PX_1, the second pixel PX_2, the third pixel PX_3, and the fourth pixel PX_4 included in the pixel group GPX may correspond to the pixel PX in FIG. 1.

Each of the first pixel PX_1, the second pixel PX_2, the third pixel PX_3, and the fourth pixel PX_4 may have a 2PD structure including two PDs. The first pixel PX_1 may include a first PD PD1, a second PD PD2, a first transmission transistor TX1, and a second transmission transistor TX2, the second pixel PX_2 may include a third PD PD3, a fourth PD PD4, a third transmission transistor TX3, and a fourth transmission transistor TX4, the third pixel PX_3 may include a fifth PD PD5, a sixth PD PD6, a fifth transmission transistor TX5, and a sixth transmission transistor TX6, and the fourth pixel PX_4 may include a seventh PD PD7, an eighth PD PD8, a seventh transmission transistor TX7, and an eighth transmission transistor TX8. In the inventive concepts, transmission transistors connected to one PD may have a dual vertical transmission gate structure. The dual vertical transmission gate structure may mean that there are two vertical transmission gates corresponding to one PD. The two vertical transmission gates of the dual vertical transmission structure may be collectively referred to as a dual vertical transmission gate. The same transmission control signal may be applied to each of the two vertical transmission gates included in the dual vertical transmission structure.

The read circuit PX_C may process electrons generated by each of the first through eighth PDs PD1 through PD8, and output the electrical signal. In some example embodiments, the read circuit PX_C may include a first reset transistor RX1, a second reset transistor RX2, a driving transistor DX, and a selection transistor SX.

The first reset transistor RX1 and the second reset transistor RX2 may be turned on and off by a first reset control signal RS1 and a second reset control signal RS2, respectively, and when the first reset transistor RX1 and the second reset transistor RX2 are turned on, the voltage of the floating diffusion node FD may be reset to a power voltage VDD. When the voltage of the floating diffusion node FD is reset, the selection transistor SX may be turned on by the selection control signal SEL, and the reset voltage may be output to a column line COL.

According to the inventive concepts, it may be possible to determine whether the first reset transistor RX1 and the second reset transistor RX2 are turned on according to illuminance. According to some example embodiments, at low illuminance, both the first reset transistor RX1 and the second reset transistor RX2 may be turned off to output an image while capacitance of the floating diffusion node FD is small, and may thus reduce noise. According to some example embodiments, in high illuminance, the first reset transistor RX1 may be turned on to increase the capacitance of the floating diffusion node FD. Accordingly, the conversion gain may be lowered, but a full well capacity (FWC) may be covered, and thus, a dynamic range may be secured.

After the reset voltage is output to the column line COL, when the first through eighth transmission control signals TG1 through TG8 respectively corresponding to the first through eighth transmission transistors TX1 through TX8 included in each of the first through fourth pixels PX_1 through PX_4 are applied, electric charges (e.g., electrons), which are generated as the first through eighth PDs PD1 through PD8 respectively corresponding to the first through eighth transmission control signals TG1 through TG8 are exposed to light, may move to the floating diffusion node FD. The driving transistor DX may operate as a source-follower amplifier, which amplifies the voltage of the floating diffusion node FD, and when the selection transistor SX is turned on by the selection control signal SEL, the pixel voltage corresponding to the electrons generated by the PD corresponding thereto may be output to the column line COL.

FIG. 3A is a plan view of a 2PD pixel PX1 having a 2PD structure according to some example embodiments.

The 2PD pixel PX1 illustrated in FIG. 3A may include a semiconductor substrate 1100, a photoelectric conversion region 1200 formed on the semiconductor substrate 1100, a floating diffusion region 1300, vertical transmission gates 1400, an impurity region 1500, a floating diffusion region connection pad 1600, and a deep trench isolation (DTI) structure 1700. According to some example embodiments, the 2PD pixel PX1 may further include color filters 1910a and 1910b (refer to FIG. 3C) and microlenses 1900a and 1900b (refer to FIG. 3C). Descriptions of the components in FIG. 3A are given with reference to FIGS. 3C and 3D together. In some example embodiments, the 2PD pixel PX1 illustrated in FIG. 3A may correspond to any one of the first pixel PX_1, second pixel PX_2, third pixel PX_3, or fourth pixel PX_4 included in the pixel group GPX in FIG. 2. A vertical transmission gate may be referred to herein interchangeably as a vertical transfer gate, and vertical transmission gates may be referred to herein interchangeably as vertical transfer gates.

Referring to FIGS. 3A and 3C, the semiconductor substrate 1100 may include a first surface SUF1 and a second surface SUF2 opposite to the first surface SUF1. In some example embodiments, the image sensor 100 including the 2PD pixel PX1 may include an image sensor using a backside illumination (BSI) method. Accordingly, in some example embodiments, the image sensor 100 may be a BSI image sensor.

In this case, the vertical transmission gates 1400 or other transistors may be formed on the first surface SUF1 (in some example embodiments, a front side) of the semiconductor substrate 1100, and incident light may reach the photoelectric conversion region 1200 through the second surface SUF2 (in some example embodiments, a backside) of the semiconductor substrate 1100. In addition, in some example embodiments, the semiconductor substrate 1100 may include a semiconductor layer formed by using an epitaxial process. In some example embodiments, the semiconductor substrate 1100 may be formed by doping thereon impurities of a first conductive type (for example, p-type).

The photoelectric conversion region 1200 may be formed within the semiconductor substrate 1100, (e.g., between the first surface SUF1 of the semiconductor substrate 1100 and the second surface SUF2 of the semiconductor substrate 1100) and may generate charges (for example, photo charges) based on the incident light. In some example embodiments, electron-hole pairs may be generated in response to the incident light, and the photoelectric conversion region 1200 may collect these electrons or holes. According to some example embodiments, the photoelectric conversion region 1200 may include the PD, a pinned PD (PPD), a phototransistor, a photo gate, or a combination thereof.

The floating diffusion region 1300 may be formed apart from (e.g., spaced apart from, isolated from direct contact with) the photoelectric conversion region 1200 in a Z-axis direction in the semiconductor substrate 1100. In the floating diffusion region 1300, the charges generated in the photoelectric conversion region 1200 may be transferred and stored by the vertical transmission gates 1400. In some example embodiments, the floating diffusion region 1300 may be formed by doping thereon impurities of a second conductivity type (for example, n-type).

The vertical transmission gates 1400 may be formed inside a recess extending from the first surface SUF1 of the semiconductor substrate 1100 into the inside of the semiconductor substrate 1100, and on the first surface SUF1 of the semiconductor substrate 1100. According to the inventive concepts, a vertical transmission gate 1400 corresponding to any one of two photoelectric conversion regions 1200 included in the 2PD pixel PX1 of the 2PD structure may be provided as a dual vertical transmission gate (e.g., vertical transmission gates 1400, the first dual vertical transmission gate 1400a, and the second dual vertical transmission gate 1400b as shown in FIGS. 3A-3B and 3D) that includes multiple individual transmission gates corresponding to (e.g., multiple individual transmission gates on) a particular photoelectric conversion region 1200, and the number (e.g., quantity) thereof may be two. For example, as shown in FIG. 3A, According to the inventive concepts, two vertical transmission gates 1400 may be arranged apart from (e.g., spaced apart from, isolated from direct contact with) each other in a side-by-side direction (e.g., X-axis direction) on either side of the center portion of the photoelectric conversion region 1200. In some example embodiments, the center portion of the photoelectric conversion region 1200 may also mean a maximum voltage point (Vmax). For example, as shown in FIG. 3A, vertical transmission gates 1400 on opposite sides of the central portion of a given photoelectric conversion region 1200 may be understood to collectively define a dual vertical transmission gate 1400-1. In some example embodiments, the individual vertical transmission gates 1400 of a dual vertical transmission gate structure (e.g., dual vertical transmission gate 1400-1) may be collectively referred to as a vertical transmission gate.

Due to the structure of the vertical transmission gate (e.g., a dual vertical transmission gate 1400-1 including multiple vertical transmission gates 1400), a transfer path of the charges transferred from the photoelectric conversion region 1200 to the floating diffusion region 1300 may be formed in a straight line (the arrow in FIG. 3A), and the transfer efficiency may be increased, thereby improving the operational performance and/or efficiency (e.g., improved operational performance of the pixel PX1 without increasing power consumption by the pixel PX1 and/or reducing power consumption by the pixel PX1 without compromising operational performance of the pixel PX1). For example, as shown in at least FIG. 3A, based on the vertical transmission gates 1400 being spaced apart from each other in the X-axis direction, overlapping opposite side edges of the photoelectric conversion region 1200 in the Z-axis direction, and further overlapping opposite side edges of at least one floating diffusion region 1300 in the Y-axis direction, the vertical transmission gates 1400 of a dual vertical transmission gate 1400-1 may at least partially define a charge transfer path 1420 extending between opposing surfaces 1400S of the vertical transmission gates 1400 from the photoelectric conversion region 1200 to the floating diffusion region 1300 (e.g., in the Y-axis direction, as shown in at least FIG. 3A). As a result, a vertical transmission gate (e.g., provided as a dual vertical transmission gate 1400-1 as shown in FIGS. 3A-3D) may at least partially surround, e.g., in the X-axis direction (and may at least partially define) a path of charges transferred from a photoelectric conversion region to a floating diffusion region (e.g., the charge transfer path 1420), where the charge transfer path 1420 may extend linearly between the photoelectric conversion region 1200 to the floating diffusion region 1300 as shown and thereby may configure the pixel PX1 to have improved transfer efficiency and thus to have improved operational performance and/or improved power consumption efficiency. Additionally, where a pixel includes multiple photoelectric conversion regions 1200, the pixel may include multiple dual vertical transmission gates 1400-1 that may each surround (and may at least partially define) a path of charges transferred from a separate one of the photoelectric conversion regions to one or more floating diffusion regions (e.g., the charge transfer path 1420).

The impurity region 1500 may include a region formed on the transfer path (e.g., charge transfer path 1420) between the photoelectric conversion region 1200 and the floating diffusion region 1300. In some example embodiments, the impurity region 1500 may include a region formed by doping thereon impurities of the same conductivity type as impurities doped on the floating diffusion region 1300. In some example embodiments, the impurity region 1500 may be formed in a T-shape in a vertical view (the Z-axis direction).

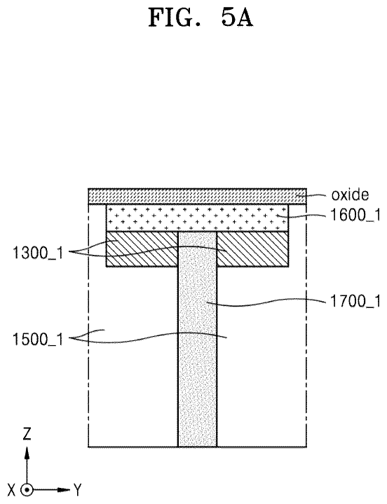

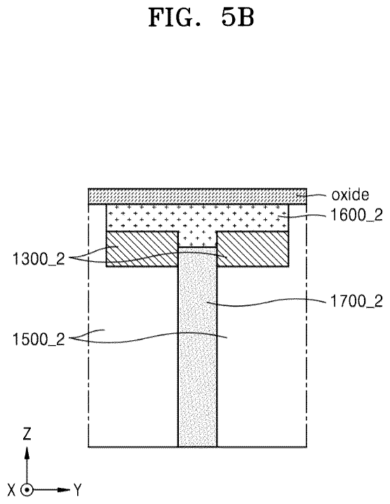

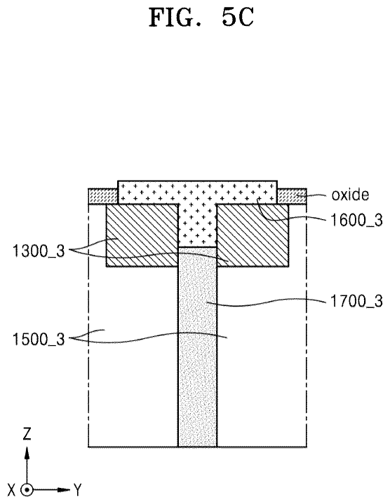

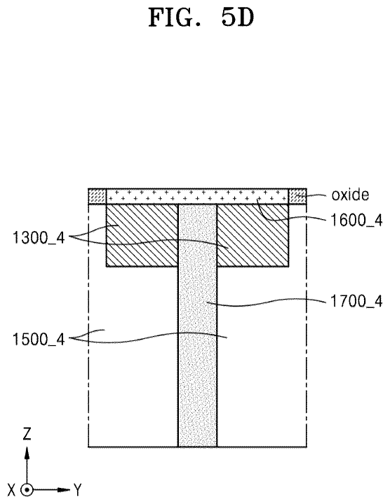

Floating diffusion region connection pads 1600 may connect the floating diffusion regions 1300, corresponding to different photoelectric conversion regions 1200, to each other. The floating diffusion region connection pad 1600 may include a poly-silicon pad. In addition, the floating diffusion region connection pad 1600 may include a material capable of transferring charges stored in the floating diffusion regions 1300 (e.g., a dopant; a metal, including for example aluminum; etc.). Some example embodiments of the floating diffusion region connection pad 1600 are described below with reference to FIGS. 5A through 5D.

The 2PD pixel PX1 may further include the DTI structure 1700 formed to surround each 2PD pixel PX1. The DTI structure 1700 may extend from the first surface SUF1 of the semiconductor substrate 1100 to a certain depth, or may be formed to completely penetrate the semiconductor substrate 1100 from the first surface SUF1 to the second surface SUF2 of the semiconductor substrate 1100. In some example embodiments, the DTI structure 1700 may be formed from the second surface SUF2 of the semiconductor substrate 1100 to a certain depth or to completely penetrate the semiconductor substrate 1100. In some example embodiments, the DTI structure 1700 may include any insulating material, such as silicon oxide (SiOx), silicon nitride (SiNx), and hafnium oxide (HfOx). As the pixel PX1 is separated from (e.g., physically, electrically, and/or optically isolated from) adjacent pixels PX1 by the DTI structure 1700, optical and/or electrical crosstalk between pixels PX1 may be reduced, minimized, or prevented.

The DTI structure 1700 according to some example embodiments of FIG. 3A may be provided in a DTI edge cut (DEC) structure. According to some example embodiments, the DTI structure 1700 in FIG. 3A may include a DTI structure which partially separates (e.g., partitions) the left side pixel region and the right side pixel region of the 2PD pixel PX1 of the 2PD structure. According to some example embodiments, the left side pixel region and the right side pixel region of the 2PD pixel PX1 of the 2PD structure may not be completely separated. As shown, the DTI structure may separate (e.g., in the X-axis direction) portions of the left side pixel region and the right side pixel region of the 2PD pixel PX1 that include at least the respective vertical transmission gates 1400 and impurity regions 1500 of the left side pixel region and the right side pixel region of the 2PD pixel PX1. The left side pixel region and the right side pixel region of the 2PD pixel PX1 of the 2PD structure may be partially separated by the DTI structure 1700 in which the edge region (e.g., a periphery region 1702 of the DTI structure 1700) arranged at the center of the 2PD pixel PX1 is cut. By using the structure described above, uniform doping may be performed along the side of the DTI structure 1700 by using a method such as plasma doping, and a potential barrier, which distributes one of the two PDs included in the 2PD pixel PX1 of the 2PD structure, may be formed to secure a high (e.g., increased or maximized) charge overflow barrier (COB). Therefore, based on using such structure of the DTI structure 1700 in the pixel PX1, the operational performance and/or efficiency of the pixel PX1 may be improved based on securing a high charge overflow barrier (COB) as a result of providing a DTI structure 1700 that partially separates the separate pixel regions of the 2PD pixel PX1 of the 2PD structure, including structures where the edge region (e.g., a periphery region 1702 of the DTI structure 1700) arranged at the center of the 2PD pixel PX1 is cut.

For the 2PD pixel PX1 of the 2PD structure in FIG. 3A, the left side pixel region has been mainly described, but the descriptions of the left side pixel region may also be applied equally to the right side pixel region. In addition, the floating diffusion region 1300 and the floating diffusion region connection pad 1600 illustrated in the left side pixel region are not shown in the right side pixel region in FIG. 3A, but this is for convenience of explanation, and it should be understood that it does not mean that the right side pixel region does not include a floating diffusion region and a floating diffusion region connection pad. In FIG. 3A, two separate instances of the floating diffusion region 1300 may be present in the separate pixel regions with a portion of the DTI structure 1700 extending therebetween, but it will be understood that the various instances of the floating diffusion region in a given pixel may be referred to collectively as a particular (e.g., singular) floating diffusion region of the pixel (e.g., floating diffusion region 1300 of the pixel PX1). As shown in FIG. 3A, In FIG. 3A, two separate instances of the impurity region 1500 are present in the separate pixel regions with a portion of the DTI structure 1700 extending therebetween, but it will be understood that the various instances of the impurity region in a given pixel may be referred to collectively as a particular (e.g., singular) impurity region of the pixel (e.g., impurity region 1500 of the pixel PX1).

FIG. 3B is a plan view of a pixel array PX11 including 2PD pixels according to some example embodiments. FIG. 3C is a cross-sectional view taken along line A-A′ in the plan view of FIG. 3B. FIG. 3D is a cross-sectional view taken along line B-B′ of FIG. 3B.

Referring to FIG. 3B, the pixel array PX11 formed by arranging 2PD pixels PX1a, PX1b, PX1c, and PX1d of the 2PD structure in a 2×2 form is illustrated. The 2PD pixels PX1a, PX1b, PX1c, and PX1d of the 2PD structure illustrated in FIG. 3B may correspond to the 2PD pixel PX1 of the 2PD structure described in FIG. 3A. According to some example embodiments, the pixel array PX11 of FIG. 3B may correspond to the pixel group GPX illustrated in FIG. 2.

Referring to FIG. 3B, in some example embodiments the 2PD pixel PX1a includes a first photoelectric conversion region 1200a, a third photoelectric conversion region 1200c, a first floating diffusion region 1300a, and first and third dual vertical transmission gates 1400a and 1400c, and the 2PD pixel PX1c includes a second photoelectric conversion region 1200b, a fourth photoelectric conversion region 1200d, a second floating diffusion region 1300b, and second and fourth dual vertical transmission gates 1400b and 1400d.

Referring to FIG. 3B, floating diffusion region connection pads 1600a, 1600b, 1600c, and 1600d for connecting to each other floating diffusion regions included in different pixels, and metal contacts 1800a, 1800b, 1800c, and 1800d respectively connected to the floating diffusion region connection pads 1600a, 1600b, 1600c, and 1600d are illustrated. In some example embodiments, each of the metal contacts 1800a, 1800b, 1800c, and 1800d may include a metal material (e.g., aluminum). By using the structure described above, the conversion gains of the 2PD pixels PX1a, PX1b, PX1c, and PX1d of the 2PD structure may be reduced.

Referring to FIG. 3C, a cross-sectional view of the plan view of FIG. 3B taken along line A-A′ is illustrated. Referring to FIG. 3C, semiconductor substrates 1100a and 1100b respectively included in the 2PD pixels PX1a and PX1c, the first and second photoelectric conversion regions 1200a and 1200b, the first and second floating diffusion regions 1300a and 1300b, the first and second impurity regions 1500a and 1500b, a floating diffusion region connection pad 1600a, a metal contact 1800a, the DTI structure 1700, microlenses 1900a and 1900b, and color filters 1910a and 1910b are illustrated.

The first and second floating diffusion regions 1300a and 1300b respectively included in 2PD pixels PX1a and PX1c of different 2PD structures may be connected via the floating diffusion region connection pad 1600a, and the floating diffusion region connection pad 1600a may be connected to (e.g., may contact) the metal contact 1800a formed after extending in the Z-axis direction. The first impurity region 1500a may be between the first photoelectric conversion region 1200a and the first floating diffusion region 1300a in 2PD pixel PX1a, and the second impurity region 1500b between the second photoelectric conversion region 1200b and the second floating diffusion region 1300b in 2PD pixel PX1c. The floating diffusion region connection pad 1600a may be formed in a structure in which a contact area with the first and second floating diffusion regions 1300a and 1300b is increased.

Referring to FIG. 3D, a cross-sectional view of the plan view of FIG. 3B taken along line B-B′ is illustrated. Referring to FIG. 3D, the first photoelectric conversion region 1200a and the first dual vertical transmission gate 1400a are illustrated. The first photoelectric conversion region 1200a and the first dual vertical transmission gate 1400a may be formed apart from each other (e.g., in the Z-axis direction). According to some example embodiments, the first dual vertical transmission gate 1400a may be formed at locations symmetrical to each other with respect to a center point of the first photoelectric conversion region 1200a. For example, as shown in FIG. 3D, the first dual vertical transmission gate 1400a may be formed at locations symmetrical to each other with respect to a center point of the first photoelectric conversion region 1200a such that the first dual vertical transmission gate 1400a is provided by a plurality of vertical transmission gates that are spaced apart from each other in a horizontal direction (e.g., the X-axis direction) and overlap opposite side edges of the first photoelectric conversion region 1200a in the Z-axis direction) and thus at least partially define a charge transfer path 1420 between the opposite side surfaces of the plurality of vertical transmission gates. Accordingly, it will be understood that the first dual vertical transmission gate 1400a may be interchangeably referred to as a first plurality of vertical transmission gates formed at locations symmetrical to each other with respect to a center point of the first photoelectric conversion region 1200a. Similarly, the second dual vertical transmission gate 1400b may be interchangeably referred to as a second plurality of vertical transmission gates formed at locations symmetrical to each other with respect to a center point of the second photoelectric conversion region 1200b, the third dual vertical transmission gate 1400c may be interchangeably referred to as a third plurality of vertical transmission gates formed at locations symmetrical to each other with respect to a center point of the third photoelectric conversion region 1200c, and the fourth dual vertical transmission gate 1400d may be interchangeably referred to as a fourth plurality of vertical transmission gates formed at locations symmetrical to each other with respect to a center point of the fourth photoelectric conversion region 1200d.

A pixel according to some example embodiments may unify a metal contact by connecting floating diffusion regions included in different pixels via a floating diffusion region connection pad. A pixel according to some example embodiments may be applied to a structure, in which not only the center portion of the pixel but the edge region thereof (e.g., periphery region) are DTI-opened, and the location of the floating diffusion region may be variously applied. In addition, the number (e.g., quantity) of the floating diffusion regions, which may be connected via the floating diffusion region connection pad, may also vary. A pixel structure according to the inventive concepts may be good in maintaining FWC and COB, and thus may have improved operational performance and/or efficiency (e.g., power consumption efficiency) based on having improved FWC and/or COB based on the metal contact structure, floating diffusion region structure, and/or floating diffusion connection pad structures according to some example embodiments.

Some example embodiments thereof are described below.

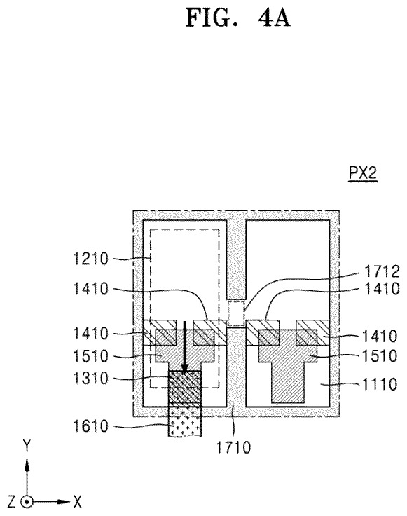

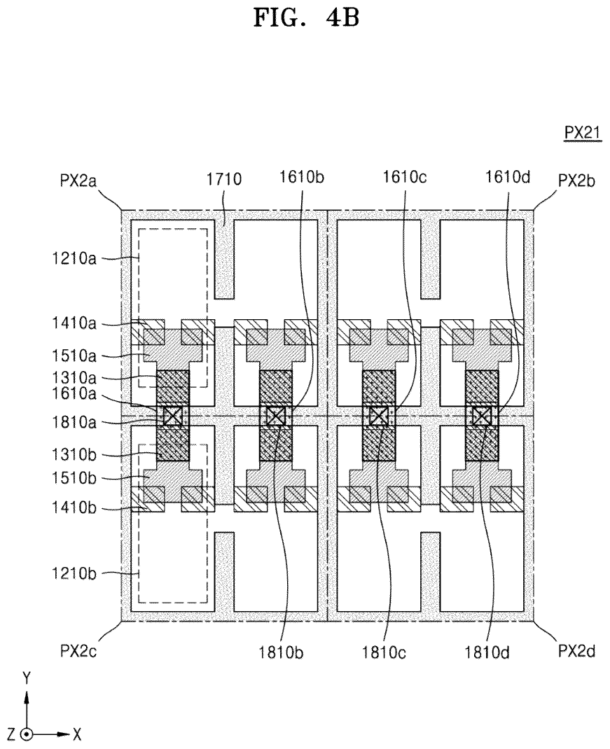

FIG. 4A is a plan view of a 2PD pixel PX2 according to some example embodiments. In descriptions with respect to FIG. 4A, duplicate descriptions given with reference to FIG. 3A are omitted.

According to some example embodiments, the 2PD pixel PX2 of FIG. 4A may include a semiconductor substrate 1110, a photoelectric conversion region 1210, a floating diffusion region 1310, a vertical transmission gate 1410, an impurity region 1510, a floating diffusion region connection pad 1610, and a DTI structure 1710.

Descriptions of the semiconductor substrate 1110, the photoelectric conversion region 1210, the floating diffusion region 1310, the vertical transmission gate 1410 (e.g., dual vertical transmission gate), the impurity region 1510, and the floating diffusion region connection pad 1610 illustrated in FIG. 4A may be the same as the descriptions of the corresponding components, for example the semiconductor substrate 1100, the photoelectric conversion region 1200, the floating diffusion region 1300, the vertical transmission gate 1400, the impurity region 1500, and the floating diffusion region connection pad 1600, respectively, in the 2PD pixel PX1 of FIG. 3A, and thus, duplicate descriptions are omitted.

The DTI structure 1710 illustrated in FIG. 4A may have a DTI center cut (DCC) structure. According to some example embodiments, a left side pixel region and a right side pixel region of the 2PD pixel PX2 of FIG. 4A may be partially separated by the DTI structure 1710. Compared to FIG. 3A, the 2PD pixel PX2 of FIG. 4A may include the DTI structure 1710 in which a region (e.g., a center portion region 1712 of the DTI structure 1710) corresponding to the center portion of the 2PD pixel PX2 is cut.

FIG. 4B is a plan view of a pixel array PX21 including 2PD pixels, according to some example embodiments.

Referring to FIG. 4B, the pixel array PX21 formed by arranging 2PD pixels PX2a, PX2b, PX2c, and PX2d of a 2PD structure in a 2×2 form is illustrated. The 2PD pixels PX2a, PX2b, PX2c, and PX2d of a 2PD structure illustrated in FIG. 4B may correspond to the 2PD pixel PX2 of the 2PD structure described with reference to FIG. 4A.

Referring to FIG. 4B, in some example embodiments the 2PD pixel PX2a includes a first photoelectric conversion region 1210a, a first floating diffusion region 1310a, a first dual vertical transmission gate 1410a, a first impurity region 1510a, and the 2PD pixel PX2c includes a second photoelectric conversion region 1210b, a second floating diffusion region 1310b, a second vertical transmission gate 1410b, a second impurity region 1510b.

Referring to FIG. 4B, floating diffusion region connection pads 1610a, 1610b, 1610c, and 1610d for connecting to each other floating diffusion regions included in different pixels, and metal contacts 1810a, 1810b, 1810c, and 1810d respectively connected to the floating diffusion region connection pads 1610a, 1610b, 1610c, and 1610d are illustrated. By using the structure described above, the conversion gains of the 2PD pixels PX2a, PX2b, PX2c, and PX2d of a 2PD structure may be reduced.

FIGS. 5A, 5B, 5C, and 5D illustrate various example embodiments capable of connecting floating diffusion nodes of 2PD pixels, according to some example embodiments. According to some example embodiments, FIGS. 5A through 5D may be cross-sectional views corresponding to a region C in FIG. 3C.

Referring to FIG. 5A, a DTI structure 1700_1 arranged between impurity regions 1500_1 is illustrated, and floating diffusion regions 1300_1 extending in a Y-axis direction based on the DTI structure 1700_1 are illustrated. A floating diffusion region connection pad 1600_1 may be formed on the floating diffusion regions 1300_1 and the DTI structure 1700_1. According to some example embodiments, an insulating layer oxide may be formed on the floating diffusion region connection pad 1600_1. According to some example embodiments, including the example embodiments shown in FIG. 5A, the upper end portions of the floating diffusion regions 1300_1 and the DTI structure 1700_1 may have the same height (e.g., may be coplanar or substantially coplanar as shown in FIG. 5A), for example such that an upper end height of the DTI structure 1700_1 is identical to an upper end height of the floating diffusion regions 1300_1, and the floating diffusion region connection pad 1600_1 may be formed on the upper end portions of the floating diffusion regions 1300_1 and the DTI structure 1700_1 having the same height. According to some example embodiments, the floating diffusion region connection pad 1600_1 may be formed in a recess region where the impurity region 1500_1 is partially etched. According to some example embodiments, the floating diffusion region connection pad 1600_1 may be formed in a recess region where a semiconductor substrate corresponding thereto is partially etched.

Referring to FIG. 5B, a DTI structure 1700_2 arranged between impurity regions 1500_2 is illustrated, and floating diffusion regions 1300_2 extending in the Y-axis direction based on the DTI structure 1700_2 are illustrated. Referring to FIG. 5B, a height of an upper end portion of the floating diffusion regions 1300_2 may be different from a height of an upper end portion of the DTI structure 1700_2, such that the upper end portion of the floating diffusion regions 1300_2 and the upper end portion of the DTI structure 1700_2 are offset from each other in the Z-axis direction and are not coplanar with each other, for example such that an upper end height of the DTI structure 1700_2 is different from an upper end height of the floating diffusion regions 1300_2. Referring to FIG. 5B, the height (e.g., distance in the Z-axis direction from a reference location, such as the second surface SUF2 of the semiconductor substrate 1100) of the upper end portion of the floating diffusion regions 1300_2 may be greater than the height (e.g., distance in the Z-axis direction from the same reference location) of the upper end portion of the DTI structure 1700_2. A floating diffusion region connection pad 1600_2 may be formed on the floating diffusion regions 1300_2 and the DTI structure 1700_2. By using the structure described above, the contact area between the floating diffusion regions 1300_2 of the floating diffusion region connection pad 1600_2 may increase, and accordingly, resistance therebetween may decrease. According to some example embodiments, the floating diffusion region connection pad 1600_2 may be formed in a recess region where the impurity region 1500_2 is partially etched. According to some example embodiments, the floating diffusion region connection pad 1600_2 may be formed in a recess region where a semiconductor substrate corresponding thereto is partially etched.

Referring to FIG. 5C, a DTI structure 1700_3 arranged between impurity regions 1500_3 is illustrated, and floating diffusion regions 1300_3 extending in the Y-axis direction based on the DTI structure 1700_3 are illustrated. Referring to FIG. 5C, an upper end height of the DTI structure 1700_3 may be different from an upper end height of the floating diffusion regions 1300_3, for example a height (e.g., distance in the Z-axis direction from a reference location, such as the second surface SUF2 of the semiconductor substrate 1100) of an upper end portion of the floating diffusion regions 1300_3 may be greater than a height (e.g., distance in the Z-axis direction from the same reference location) of an upper end portion of the DTI structure 1700_3. A floating diffusion region connection pad 1600_3 may be formed on the floating diffusion regions 1300_3 and the DTI structure 1700_3. By using the structure described above, the contact area between the floating diffusion regions 1300_3 of the floating diffusion region connection pad 1600_3 may increase, and accordingly, resistance therebetween may decrease. According to some example embodiments, the floating diffusion region connection pad 1600_3 may be formed without etching the impurity region 1500_3 or a semiconductor substrate corresponding thereto. Accordingly, the floating diffusion region connection pad 1600_3 may be in a region where the semiconductor substrate 1100 is not recessed (e.g., external to a volume space defined by outermost surfaces of the semiconductor substrate 1100).

Referring to FIG. 5D, a DTI structure 1700_4 arranged between impurity regions 1500_4 is illustrated, and floating diffusion regions 1300_4 extending in the Y-axis direction based on the DTI structure 1700_4 are illustrated. Referring to FIG. 5D, a floating diffusion region connection pad 1600_4 may be formed on the floating diffusion regions 1300_4 and the DTI structure 1700_4. The upper end portions of the floating diffusion regions 1300_4 and the DTI structure 1700_4 may have the same height (e.g., may be coplanar or substantially coplanar), for example such that an upper end height of the DTI structure 1700_4 is identical to an upper end height of the floating diffusion regions 1300_4, and the floating diffusion region connection pad 1600_4 may be formed on the floating diffusion regions 1300_4 and the DTI structure 1700_4 having the same upper end portion height. According to some example embodiments, the floating diffusion region connection pad 1600_4 may be formed without etching the impurity region 1500_4 or a semiconductor substrate corresponding thereto. Accordingly, the floating diffusion region connection pad 1600_4 may be in a region where the semiconductor substrate 1100 is not recessed (e.g., external to a volume space defined by outermost surfaces of the semiconductor substrate 1100).

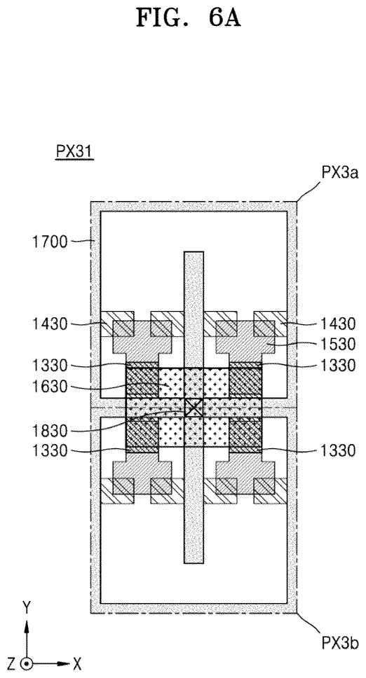

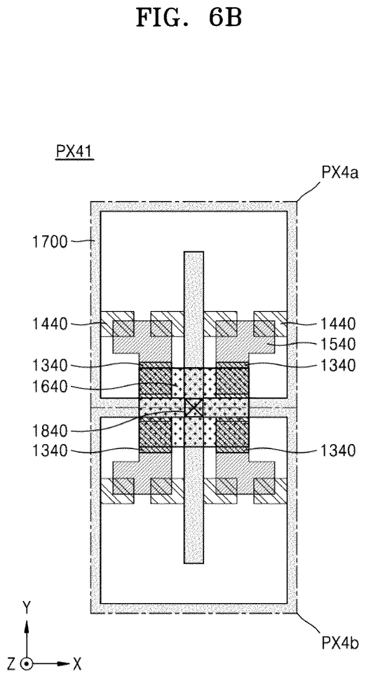

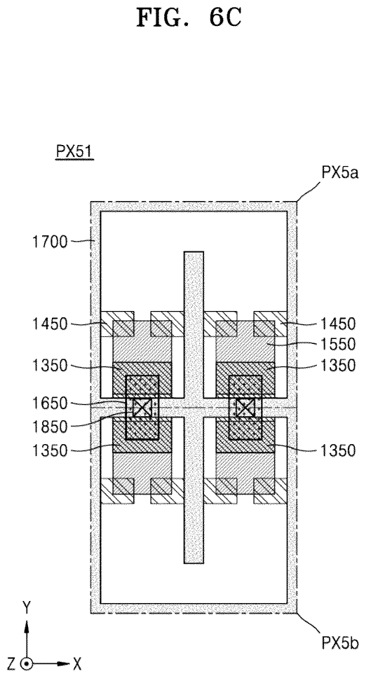

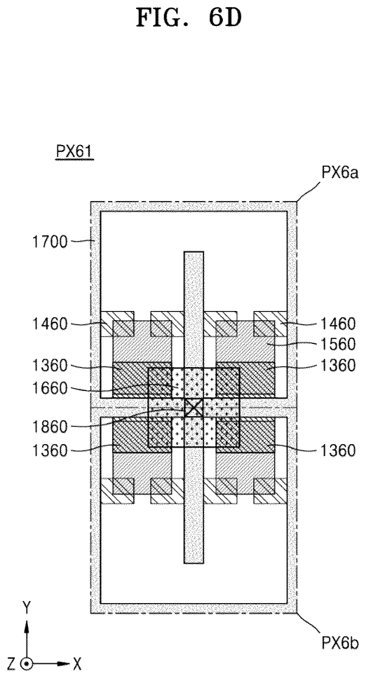

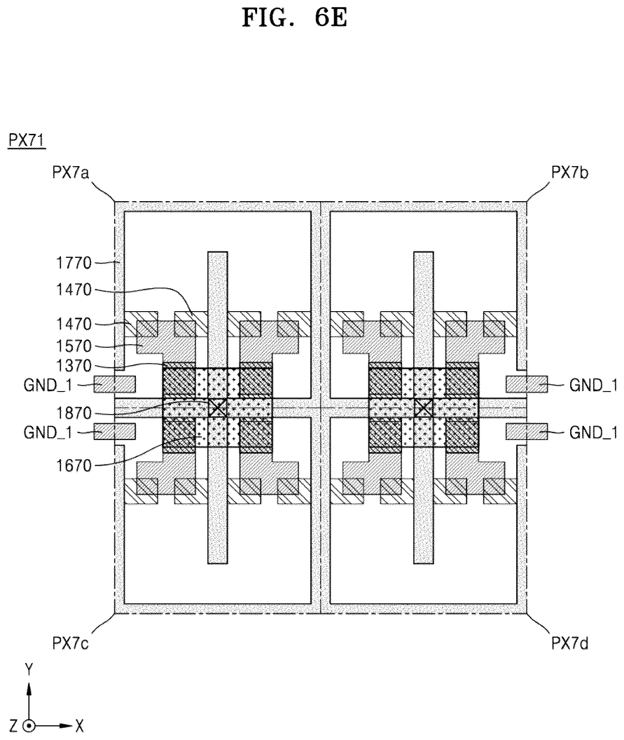

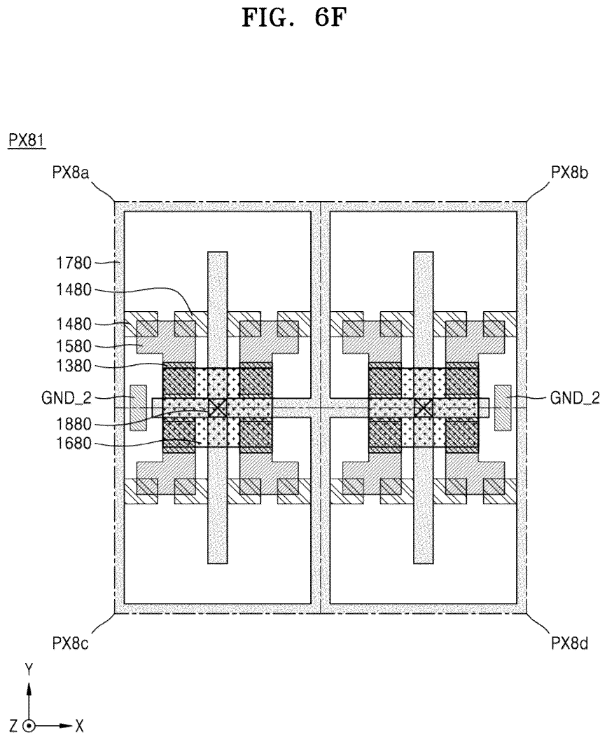

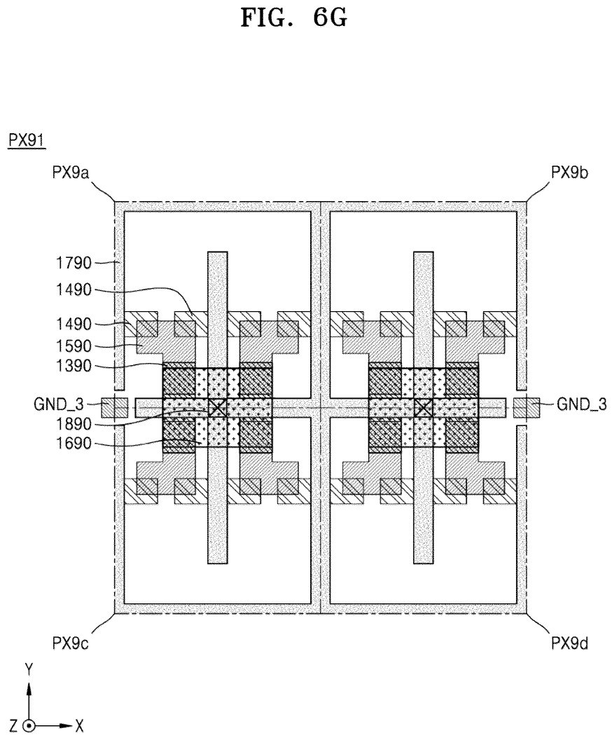

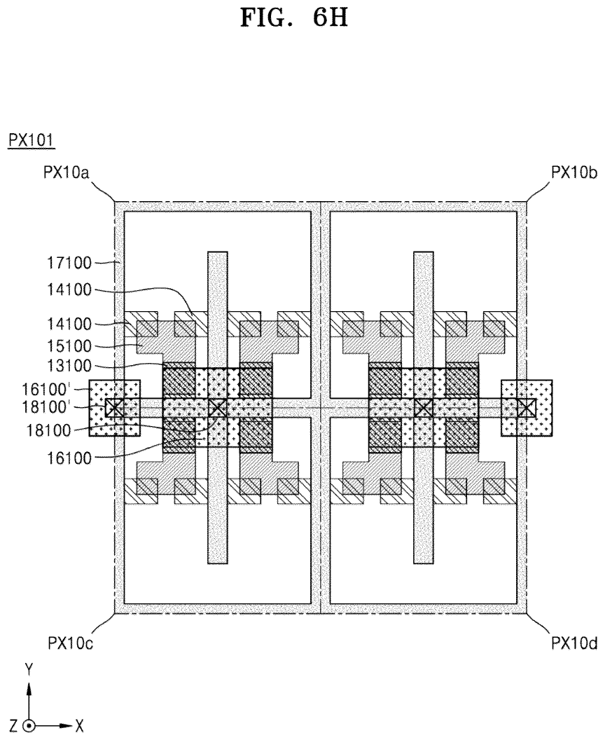

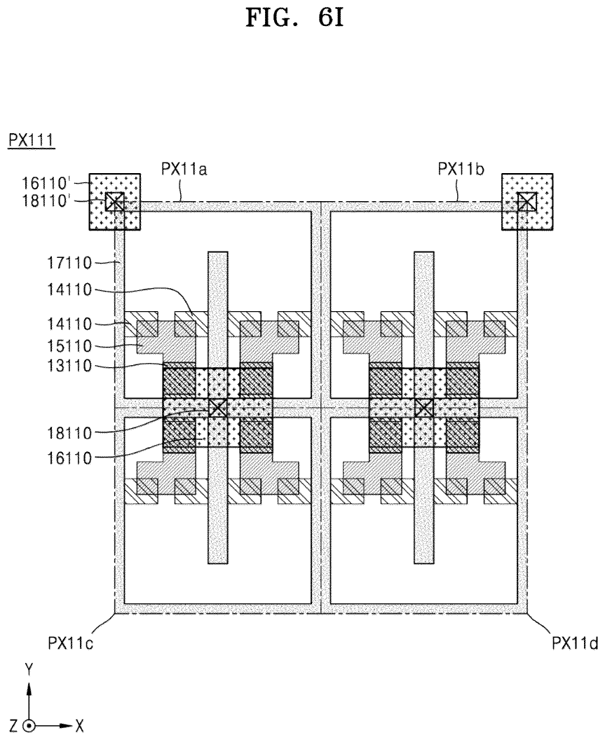

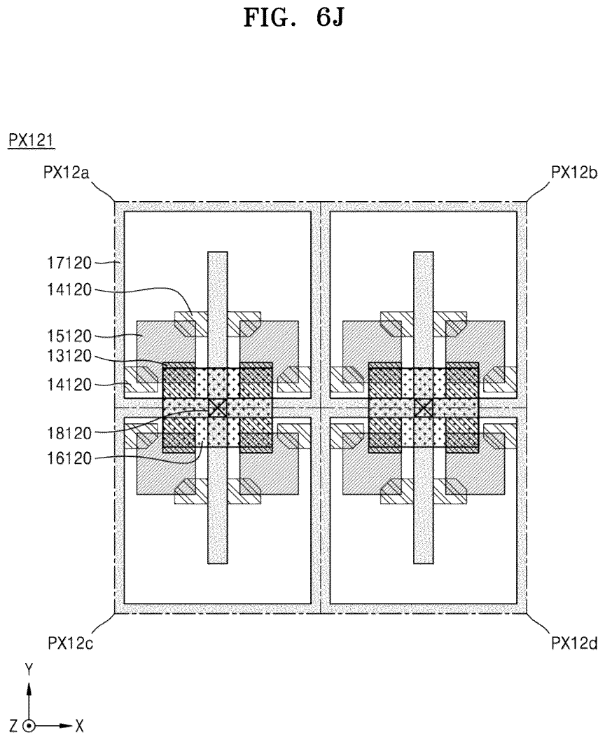

FIGS. 6A, 6B, 6C, 6D, 6E, 6F, 6G, 6H, 6I, and 6J respectively illustrate layout structures of pixel arrays including 2PD pixels, according to some example embodiments. It should be understood that among the components included in the pixel arrays illustrated in FIGS. 6A through 6J, the components not mentioned are the same as those described in the pixel array described above.

Referring to FIG. 6A, a pixel array PX31 formed by arranging 2PD pixels PX3a and PX3b of a 2PD structure side-by-side in the Y-axis direction is illustrated. The 2PD pixels PX3a and PX3b of the 2PD structure included in the pixel array PX31 may have a symmetrical structure.

The 2PD pixel PX3a illustrated in FIG. 6A may include a floating diffusion region 1330, a vertical transmission gate 1430, an impurity region 1530, a floating diffusion region connection pad 1630, and a metal contact 1830. Because a structure of the floating diffusion region 1330, the vertical transmission gate 1430, and the impurity region 1530 among the components included in the 2PD pixel PX3a illustrated in FIG. 6A is the same as the structure of the components corresponding thereto included in the 2PD pixel PX1 illustrated in FIG. 3A, for example the floating diffusion region 1300, the vertical transmission gate 1400, and the impurity region 1500, respectively, descriptions thereof are omitted.

Referring to FIG. 6A, the floating diffusion region connection pad 1630 may be provided in a structure where all four floating diffusion regions 1330 included in the 2PD pixels PX3a and PX3b of the 2PD structure are connected thereto. By providing one floating diffusion region connection pad 1630 connecting all four floating diffusion regions 1330 thereto, the structure of the 2PD pixel PX31 may be simplified by reducing the number of metal contacts 1830.

Referring to FIG. 6B, a pixel array PX41 formed by arranging 2PD pixels PX4a and PX4b of a 2PD structure side-by-side in the Y-axis direction is illustrated. The 2PD pixels PX4a and PX4b of the 2PD structure included in the pixel array PX41 may have a symmetrical structure.

The 2PD pixel PX4a illustrated in FIG. 6B may include a floating diffusion region 1340, a vertical transmission gate 1440, an impurity region 1540, a floating diffusion region connection pad 1640, and a metal contact 1840. Because a structure of the floating diffusion region 1340, the vertical transmission gate 1440, the floating diffusion region connection pad 1640, and the metal contact 1840 among the components included in the 2PD pixel PX4a illustrated in FIG. 6B is the same as the structure of the components corresponding thereto included in the 2PD pixel PX3a illustrated in FIG. 6A, for example the floating diffusion region 1330, the vertical transmission gate 1430, the floating diffusion region connection pad 1630, and the metal contact 1830, respectively, descriptions thereof are omitted.

Referring to FIG. 6B, the shape of the impurity region 1540 may be provided in an ‘L’ shape. The impurity region 1540 may be provided in the form of an ‘L’ shape, and the impurity region 1540 may be arranged in a symmetrical structure with respect to the center of the pixel array PX41. As a result, the floating diffusion regions 1340 at the ends of the ‘L’ shape among the shapes of the impurity regions 1540 may be adjacent to each other, and accordingly, the area of the floating diffusion region connection pad 1640 may be reduced. In addition, by using the impurity region 1540 of the ‘L’ shape structure, the capacitance of the floating diffusion region 1340 may be reduced, and the conversion gain of the 2PD pixel PX41 may increase.

Referring to FIG. 6C, a pixel array PX51 formed by arranging 2PD pixels PX5a and PX5b of a 2PD structure side-by-side in the Y-axis direction is illustrated. The 2PD pixels PX5a and PX5b of the 2PD structure included in the pixel array PX51 may have a symmetrical structure.

The 2PD pixel PX5a illustrated in FIG. 6C may include a floating diffusion region 1350, a vertical transmission gate 1450, an impurity region 1550, a floating diffusion region connection pad 1650, and a metal contact 1850. Because a structure of the vertical transmission gate 1450, the floating diffusion region connection pad 1650, and the metal contact 1850 among the components included in the 2PD pixel PX5a illustrated in FIG. 6C is the same as the structure of the components corresponding thereto included in the 2PD pixel PX1 illustrated in FIG. 3B, for example the first dual vertical transmission gate 1400a, the floating diffusion region connection pad 1600a, and the metal contact 1800a, respectively, descriptions thereof are omitted.

Referring to FIG. 6C, the impurity region 1550 may be provided in a square shape. The floating diffusion region 1350 may be formed to have an X-axis direction length corresponding to the square shape of the impurity region 1550. By using the structure described above, electrons generated by the photoelectric conversion region may be easily transmitted to the floating diffusion node, thereby improving the operational performance and/or efficiency (e.g., power consumption efficiency) of an image sensor including the pixel array PX51.

Referring to FIG. 6D, a pixel array PX61 formed by arranging 2PD pixels PX6a and PX6b of a 2PD structure side-by-side in the Y-axis direction is illustrated. The 2PD pixels PX6a and PX6b of the 2PD structure included in the pixel array PX61 may have a symmetrical structure.

The 2PD pixel PX6a illustrated in FIG. 6D may include a floating diffusion region 1360, a vertical transmission gate 1460, an impurity region 1560, a floating diffusion region connection pad 1660, and a metal contact 1860. Because a structure of the floating diffusion region 1360, the vertical transmission gate 1460, and the impurity region 1560 among the components included in the 2PD pixel PX6a illustrated in FIG. 6D is the same as the structure of the components corresponding thereto included in the 2PD pixel PX5a illustrated in FIG. 6C, for example the floating diffusion region 1350, the vertical transmission gate 1450, and impurity region 1550, respectively, descriptions thereof are omitted.

Referring to FIG. 6D, the floating diffusion region connection pad 1660 may be formed to connect all four floating diffusion regions 1360, and the metal contact 1860 may be formed at the center portion of the floating diffusion region connection pad 1660.

Referring to FIG. 6E, a pixel array PX71 formed by arranging 2PD pixels PX7a, PX7b, PX7c, and PX7d of the 2PD structure in a 2×2 form is illustrated. The 2PD pixels PX7a, PX7b, PX7c, and PX7d of the 2PD structure included in the pixel array PX71 may have a symmetrical structure.

Referring to FIG. 6E, the 2PD pixel PX7a may include a floating diffusion region 1370, a vertical transmission gate 1470, an impurity region 1570, a floating diffusion region connection pad 1670, a metal contact 1870, a DTI structure 1770, and ground GND_1. Because a structure of the floating diffusion region 1370, the vertical transmission gate 1470, the impurity region 1570, the floating diffusion region connection pad 1670, and the metal contact 1870 among the components included in the 2PD pixel PX7a illustrated in FIG. 6E is the same as the structure of the components corresponding thereto included in the 2PD pixel PX4a illustrated in FIG. 6B, for example the floating diffusion region 1340, the vertical transmission gate 1440, the impurity region 1540, the floating diffusion region connection pad 1640, and the metal contact 1840, respectively, descriptions thereof are omitted.

Referring to FIG. 6E, one side of a DTI structure surrounding the pixel PX7a in the DTI structure 1770 may be provided in a cut structure, and the ground GND_1 may be formed in the cut region. This may be applied equally to all 2PD pixels PX7a, PX7b, PX7c, and PX7d included in the pixel array PX71.

Referring to FIG. 6F, a pixel array PX81 formed by arranging 2PD pixels PX8a, PX8b, PX8c, and PX8d of the 2PD structure in a 2×2 form is illustrated. The 2PD pixels PX8a, PX8b, PX8c, and PX8d of the 2PD structure included in the pixel array PX81 may have a symmetrical structure.

Referring to FIG. 6F, the 2PD pixel PX8a may include a floating diffusion region 1380, a vertical transmission gate 1480, an impurity region 1580, a floating diffusion region connection pad 1680, a metal contact 1880, a DTI structure 1780, and ground GND_2. Because a structure of the floating diffusion region 1380, the vertical transmission gate 1480, the impurity region 1580, the floating diffusion region connection pad 1680, and the metal contact 1880 among the components included in the 2PD pixel PX8a illustrated in FIG. 6F is the same as the structure of the components corresponding thereto included in the 2PD pixel PX4a illustrated in FIG. 6B, for example the floating diffusion region 1340, the vertical transmission gate 1440, the impurity region 1540, the floating diffusion region connection pad 1640, and the metal contact 1840, respectively, descriptions thereof are omitted.

Referring to FIG. 6F, the DTI structure 1780 may be provided in a cut structure, where a region on one side of the DTI structure 1780 is cut for separating some pixels (PX8a and PX8c) among pixels included in the pixel array PX81, and the ground GND_2 may be formed in the cut region. This feature may be equally applied to other pixels (PX8b and PX8d) included in the pixel array PX81.

According to FIGS. 6E and 6F, by forming the grounds GND_1 and GND_2 separately, the degree of freedom of the layout may be increased.

Referring to FIG. 6G, a pixel array PX91 formed by arranging 2PD pixels PX9a, PX9b, PX9c, and PX9d of the 2PD structure in a 2×2 form is illustrated. The 2PD pixels PX9a, PX9b, PX9c, and PX9d of the 2PD structure included in the pixel array PX91 may have a symmetrical structure.

Referring to FIG. 6G, the 2PD pixel PX9a may include a floating diffusion region 1390, a vertical transmission gate 1490, an impurity region 1590, a floating diffusion region connection pad 1690, a metal contact 1890, a DTI structure 1790, and ground GND_3. Because a structure of the floating diffusion region 1390, the vertical transmission gate 1490, the impurity region 1590, the floating diffusion region connection pad 1690, and the metal contact 1890 among the components included in the 2PD pixel PX9a illustrated in FIG. 6G is the same as the structure of the components corresponding thereto included in the 2PD pixel PX4a illustrated in FIG. 6B, for example the floating diffusion region 1340, the vertical transmission gate 1440, the impurity region 1540, the floating diffusion region connection pad 1640, and the metal contact 1840, respectively, descriptions thereof are omitted.

Referring to FIG. 6G, the DTI structure 1790 may be provided in a cut structure formed by cutting a region on one side of the DTI structure 1790 for separating some pixels (PX9a and PX9c) among pixels included in the pixel array PX91 and on one side of the DTI structure 1790 surrounding the corresponding pixels (PX9a and PX9c) are cut, and the ground GND_3 may be formed in the cut regions. By using the structure described above, the grounds of four adjacent pixels may be set as one, a stable etching process may be possible, and a pattern shift may be reduced, minimized, or prevented, thereby improving the manufacturing yield of defect-free image sensors having such a structure, and thus improving the reliability of image sensors having such a structure.

Referring to FIG. 6H, a pixel array PX101 formed by arranging 2PD pixels PX10a, PX10b, PX10c, and PX10d of the 2PD structure in a 2×2 form is illustrated. The 2PD pixels PX10a, PX10b, PX10c, and PX10d of the 2PD structure included in the pixel array PX101 may have a symmetrical structure.

Referring to FIG. 6H, the 2PD pixel PX10a may include a floating diffusion region 13100, a vertical transmission gate 14100, an impurity region 15100, a floating diffusion region connection pad 16100, a metal contact 18100, a DTI structure 17100, a ground pad 16100′, and a metal contact 18100′. Because a structure of the floating diffusion region 13100, the vertical transmission gate 14100, the impurity region 15100, the floating diffusion region connection pad 16100, and the metal contact 18100 among the components included in the 2PD pixel PX10a illustrated in FIG. 6H is the same as the structure of the components corresponding thereto included in the 2PD pixel PX4a illustrated in FIG. 6B, for example the floating diffusion region 1340, the vertical transmission gate 1440, the impurity region 1540, the floating diffusion region connection pad 1640, and the metal contact 1840, respectively, descriptions thereof are omitted.

Referring to FIG. 6H, the ground pad 16100′ and the metal contact 18100′ formed by using a poly pad similar to a floating diffusion region connection pad 16100 are illustrated.

Referring to FIG. 6I, a pixel array PX111 formed by arranging 2PD pixels PX11a, PX11b, PX11c, and PX11d of the 2PD structure in a 2×2 form is illustrated. The 2PD pixels PX11a, PX11b, PX11c, and PX11d of the 2PD structure included in the pixel array PX111 may have a symmetrical structure.

Referring to FIG. 6I, the 2PD pixel PX11a may include a floating diffusion region 13110, a vertical transmission gate 14110, an impurity region 15110, a floating diffusion region connection pad 16110, a metal contact 18110, a DTI structure 17110, a ground pad 16110′, and a metal contact 18110′. Because a structure of the floating diffusion region 13110, the vertical transmission gate 14110, the impurity region 15110, the floating diffusion region connection pad 16110, and the metal contact 18110 among the components included in the 2PD pixel PX11a illustrated in FIG. 6I is the same as the structure of the components corresponding thereto included in the 2PD pixel PX4a illustrated in FIG. 6B, for example the floating diffusion region 1340, the vertical transmission gate 1440, the impurity region 1540, the floating diffusion region connection pad 1640, and the metal contact 1840, respectively, descriptions thereof are omitted.

Referring to FIG. 6I, the ground pad 16110′ and the metal contact 18110′ formed by using a poly pad similar to the floating diffusion region connection pad 16110 are illustrated. Referring to FIGS. 6H and 6I, the ground pad 16110′ may be formed at various locations.

Referring to FIG. 6J, a pixel array PX121 formed by arranging 2PD pixels PX12a, PX12b, PX12c, and PX12d of the 2PD structure in a 2×2 form is illustrated. The 2PD pixels PX12a, PX12b, PX12c, and PX12d of the 2PD structure included in the pixel array PX121 may have a symmetrical structure.

Referring to FIG. 6J, the 2PD pixel PX12a may include a floating diffusion region 13120, a vertical transmission gate 14120, an impurity region 15120, a floating diffusion region connection pad 16120, a DTI structure 17120, and a metal contact 18120. Referring to FIG. 6J, the vertical transmission gate 14120 may be arranged side by side in a diagonal direction between the X-axis direction and the Y-axis direction. According to some example embodiments, the vertical transmission gates 14120 may be formed to be symmetrical to each other. According to some example embodiments, the impurity region 15120 may be provided in a square shape, and the vertical transmission gate 14120 may be arranged in a corner region of the impurity region 15120. The floating diffusion region 13120 may be formed in the remaining corner regions of the impurity region 15120 considering the transmission path of the charges generated by the vertical transmission gate 14120. The floating diffusion region connection pad 16120 may be provided in a structure capable of connecting all four floating diffusion regions 13120 to each other. The metal contact 18120 may be connected to the floating diffusion region connection pad 16120.

To solve an issue that when a pitch of pixels gradually decreases, an area of a source follower reduces, and accordingly, random noise increases, pixel structures according to the inventive concepts may provide various structures in which the conversion gain increases by reducing capacitance of a floating diffusion region. According to the inventive concepts, by using a floating diffusion region connection pad, a plurality of floating diffusion regions may be connected to each other, a structure may be simplified by connecting a metal contact, and capacitance of the floating diffusion region may be reduced.

As described herein, any devices, systems, units, blocks, circuits, controllers, processors, and/or portions thereof according to any of the example embodiments (including, for example, the image sensor 100, the pixel array 110, the row driver 120, the readout circuit 130, the ramp signal generator, the sampling circuit 132, the analog-to-digital converter (ADC) 133, the buffer 134, the timing controller 140, the signal processing circuit 150, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid-state drive memory device, storing a program of instructions, and a processor (e.g., CPU) configured to execute the program of instructions to implement the functionality and/or methods performed by some or all of any devices, systems, units, blocks, circuits, controllers, processors, and/or portions thereof according to any of the example embodiments.

While the inventive concepts have been particularly shown and described with reference to some example embodiments thereof, it will be understood that various changes in form and details may be made therein without departing from the spirit and scope of the following claims.

What is claimed is:

1. A pixel, comprising:
a semiconductor substrate including a first surface and a second surface;
a plurality of photoelectric conversion regions between the first surface and the second surface of the semiconductor substrate;
one or more floating diffusion regions on the first surface of the semiconductor substrate and spaced apart from the plurality of photoelectric conversion regions;
a plurality of vertical transmission gates configured to surround a path of charges transferred from each photoelectric conversion region of the plurality of photoelectric conversion regions to the one or more floating diffusion regions;
a floating diffusion region connection pad on the one or more floating diffusion regions; and
a metal contact connected to the floating diffusion region connection pad.

2. The pixel of claim 1, wherein the pixel further comprises a deep trench isolation (DTI) structure configured to partially separate the plurality of photoelectric conversion regions.

3. The pixel of claim 2, wherein the floating diffusion region connection pad is in a recess region where a portion of the semiconductor substrate is recessed.

4. The pixel of claim 2, wherein the floating diffusion region connection pad is in a region where the semiconductor substrate is not recessed.

5. The pixel of claim 2, wherein
the floating diffusion region connection pad is on the one or more floating diffusion regions and the DTI structure, and
an upper end height of the DTI structure is identical to an upper end height of the one or more floating diffusion regions.

6. The pixel of claim 2, wherein
the floating diffusion region connection pad is on the one or more floating diffusion regions and the DTI structure, and
an upper end height of the DTI structure is different from an upper end height of the one or more floating diffusion regions.

7. The pixel of claim 2, wherein the DTI structure comprises a structure in which a periphery region between the plurality of photoelectric conversion regions is cut.

8. A pixel array comprising a first pixel and a second pixel, wherein the first pixel includes a first photoelectric conversion region, a second photoelectric conversion region, a first floating diffusion region, and first dual vertical transmission gates spaced apart from the first photoelectric conversion region and the second photoelectric conversion region, and wherein the second pixel includes a third photoelectric conversion region, a fourth photoelectric conversion region, a second floating diffusion region, and second dual vertical transmission gates spaced apart from the third photoelectric conversion region and the fourth photoelectric conversion region, the pixel array comprising:
a floating diffusion region connection pad configured to physically connect the first floating diffusion region to the second floating diffusion region; and
a metal contact connected to the floating diffusion region connection pad.

9. The pixel array of claim 8, further comprising:
a first impurity region formed between the first photoelectric conversion region and the first floating diffusion region; and
a second impurity region formed between the third photoelectric conversion region and the second floating diffusion region.

10. The pixel array of claim 9, wherein the first impurity region and the second impurity region each have a ‘T’ shape in a top view.

11. The pixel array of claim 9, wherein the first impurity region and the second impurity region each have an ‘L’ shape in a top view.

12. The pixel array of claim 9, wherein the first impurity region and the second impurity region each have a square shape in a top view.

13. The pixel array of claim 8, further comprising a deep trench isolation (DTI) structure configured to physically separate the first pixel from the second pixel,
wherein the DTI structure is configured to partially separate the first photoelectric conversion region from the second photoelectric conversion region in the first pixel.

14. The pixel array of claim 13, wherein the DTI structure has a structure in which a center portion region between the first photoelectric conversion region and the second photoelectric conversion region is cut.

15. The pixel array of claim 13, wherein the DTI structure has a structure in which a periphery region between the first photoelectric conversion region and the second photoelectric conversion region is cut.

16. A backside illumination (BSI) image sensor, the BSI image sensor comprising:
a pixel array including a plurality of pixels configured to respectively generate a plurality of pixel signals in response to incident light; and
a signal processing circuit configured to output image data based on the plurality of pixel signals,
wherein at least one pixel of the plurality of pixels includes
a semiconductor substrate including a first surface and a second surface,
a plurality of photoelectric conversion regions between the first surface and the second surface,
one or more floating diffusion regions on the first surface and spaced apart from the plurality of photoelectric conversion regions,
a plurality of vertical transmission gates configured to surround a path of charges transferred from each photoelectric conversion region of the plurality of photoelectric conversion regions to the one or more floating diffusion regions,
a floating diffusion region connection pad on the one or more floating diffusion regions, and
a metal contact connected to the floating diffusion region connection pad.

17. The BSI image sensor of claim 16, wherein the at least one pixel further comprises a deep trench isolation (DTI) structure configured to partially separate the plurality of photoelectric conversion regions.

18. The BSI image sensor of claim 17, wherein the DTI structure comprises a structure in which a periphery region between the plurality of photoelectric conversion regions is cut.

19. The BSI image sensor of claim 18, wherein
the floating diffusion region connection pad is on the one or more floating diffusion regions and the DTI structure, and
an upper end height of the DTI structure is identical to an upper end height of the one or more floating diffusion regions.

20. The BSI image sensor of claim 18, wherein
the floating diffusion region connection pad is on the one or more floating diffusion regions and the DTI structure, and
an upper end height of the DTI structure is different from an upper end height of the one or more floating diffusion regions.
